(19) United States
(12) Patent Application Publication
(10) Pub. No.: US 2020/0168528 A1
(43) Pub. Date: May 28, 2020

(54) STACKED-DEVICE THROUGH-SILICON VIAS FOR SEMICONDUCTOR PACKAGES

(71) Applicant: Intel Corporation, Santa Clara, CA (US)

(72) Inventors: Bok Eng Cheah, Bukit Gambir (MY); Seok Ling Lim, Kulim (MY); Jenny Shio Yin Ong, Bayan Lepas (MY); Jackson Chung Peng Kong, Tanjung Tokong (MY)

(21) Appl. No.: 16/663,001

(22) Filed: Oct. 24, 2019

(30) Foreign Application Priority Data
Nov. 27, 2018 (MY) PI 2018002143

(51) Int. Cl. H01L 23/48; H01L 25/065; H01L 23/498; H01L 23/538; H01L 25/10; H01L 21/768; H01L 25/00

(52) U.S. Cl. CPC H01L 23/481; H01L 25/0657; H01L 23/49816; H01L 23/5383; H01L 25/105; H01L 2225/1023; H01L 25/50; H01L 2225/06513; H01L 2225/06541; H01L 2225/06517; H01L 21/76898

(57) ABSTRACT

Disclosed embodiments include a multi-chip package that includes an embedded reference plane between two stacked semiconductive devices, with through-silicon vias that penetrate the reference plane, including reference-voltage vias that contact the reference plane, and signal and power-delivery vias that are insulated from the reference plane. A third semiconductive device is seated with active devices and metallization on the second conductive device.

### PRIORITY APPLICATION

This application claims the benefit of priority to Malaysian Application Serial Number PI 2018002143, filed Nov. 27, 2018, which is incorporated herein by reference in its entirety.

### FIELD

This disclosure relates to through-silicon via techniques for multiple-device semiconductor apparatus.

### BACKGROUND

Semiconductive device miniaturization connected to device packaging, includes challenges to connect sufficient devices in smaller packages, while maintain electrical performance.

### BRIEF DESCRIPTION OF THE DRAWINGS

Disclosed embodiments are illustrated by way of example, and not by way of limitation, in the figures of the accompanying drawings where like reference numerals may refer to similar elements, in which:

FIG. 1 is a cross-section elevation of a stacked-device through-silicon via semiconductor package according to an embodiment;

FIG. 2 is a top plan cross section of an embedded reference plane such as a portion of the reference plane 114 depicted in FIG. 1 according to an embodiment;

FIG. 3 is a cross-section elevation of a stacked-device through-silicon via semiconductor package according to an embodiment;

FIG. 4 is a cross-section elevation of a stacked-device through-silicon via package-on-package module semiconductor package according to an embodiment;

FIG. 5A is a cross-section elevation of a through-silicon via with embedded reference-plane semiconductive device during assembly according to an embodiment;

FIG. 5B is a cross-section elevation of the through-silicon via with embedded reference-plane semiconductive device during assembly depicted in FIG. 5A after further assembly according to an embodiment;

FIG. 5C is a cross-section elevation of the through-silicon via with an embedded reference-plane semiconductive device depicted in FIG. 5B after further processing according to an embodiment;

FIG. 5D is a cross-section elevation of the through-silicon via with an embedded reference-plane semiconductive device depicted in FIG. 5C after further processing according to an embodiment;

FIG. 5E is a cross-section elevation of the through-silicon via with an embedded reference-plane semiconductive device depicted in FIG. 5D after further processing according to an embodiment

FIG. 5F is a cross-section elevation of the through-silicon via with an embedded reference-plane semiconductive device depicted in FIG. 5E after further processing according to an embodiment;

FIG. 5G is a cross-section elevation of the through-silicon via with an embedded reference-plane semiconductive device depicted in FIG. 5F during further assembly according to an embodiment;

FIG. 6 is a process flow diagram 600 according to several embodiments;

FIG. 7 is included to show an example of a higher-level device application for the disclosed embodiments.

### DETAILED DESCRIPTION

Electrical-performance degradation of 3-dimensional (3D) stacked through-silicon via (TSV) interconnects is addressed by minimizing electromagnetic crosstalk couplings, while increasing interconnect density and data-transmission rates. Disclosed embodiments include back-to-back, reference-plane sharing semiconductive devices and devices. In an embodiment, a TSV interconnect includes copper. In an embodiment, a TSV interconnect includes silver. In an embodiment, a TSV interconnect includes aluminum.

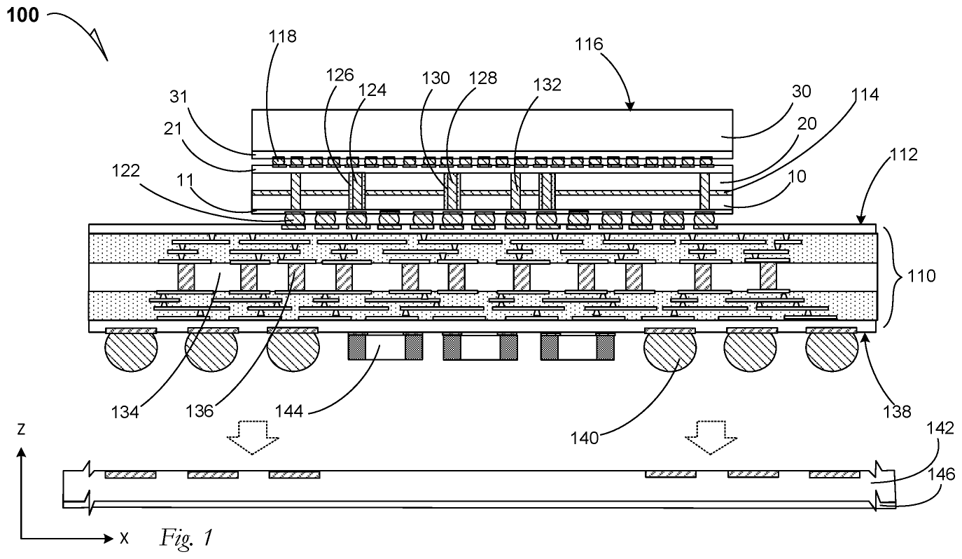

FIG. 1 is a cross-section elevation of a stacked-device through-silicon via (TSV) semiconductor package 100 according to an embodiment. A first semiconductive device 10 includes active devices and metallization 11 and it is seated on a semiconductor package substrate 110 on a die side 112. In an embodiment, the first semiconductive device 10 contacts a reference (Vss) plane 114 that is between the first semiconductive device 10 and a second semiconductive device 20 that has been assembled to the first semiconductive device 10 at the reference plane 114. In an embodiment, the second semiconductive device 20 is referred to as a second semiconductive substrate 20. In an embodiment, the second semiconductive device 20 has no active devices and metallization 21, but only uses metallization 21 to couple to a third semiconductive device 30. In an embodiment, a subsequent third semiconductive device 30′ (intersected in a different X-Z plane than that illustrated) is disposed on the second semiconductive device 20, adjacent to, and coupled to the third semiconductive device 30 through metallization 21 of the second semiconductive device 20. In an embodiment, the second semiconductive device 20 has active devices and metallization 21 and the respective first and second semiconductive devices 10 and 20 use the reference plane 114 for electromagnetic shielding and/or current return path.

In an embodiment, the embedded conductive reference plane 114 has a Z-thickness in a range from 5 micrometer (μm) to 50 μm. In an embodiment, the embedded conductive reference plane 114 includes copper. In an embodiment, the embedded conductive reference plane 114 includes silver. In an embodiment, the embedded conductive reference plane 114 includes aluminum.

In an embodiment, the third semiconductive device 30 includes active devices and metallization 31 and it has a backside surface 116. In an embodiment, the third semiconductive device 30 is flip-chip coupled to the second semiconductive device 20 by an electrical bump array such as a ball-grid array, one electrical bump of which is indicated by reference number 118. Electrical connection between the first semiconductive device 10 and the semiconductor package substrate 110 is accomplished by an electrical bump array such as a ball-grid array, one electrical bump of which is indicated by reference number 122. In an embodiment, the electrical contact 122 is part of a pin-grid array.

In an embodiment, several through-silicon vias (TSVs) couple the first and second semiconductive devices 10 and 20 through metallizations 11 and 21 to the third semiconductive device 30. In an embodiment, a power-delivery TSV 124 passes through the first and second semiconductive devices 10 and 20, and the power-delivery TSV 124 includes a conductive via 124 and power-via insulation 126. In an embodiment, a signal TSV 128 passes through the first and second semiconductive devices 10 and 20, and the signal TSV 128 includes the signal-via 128 and signal-via insulation 130. In an embodiment, a ground TSV 132 passes through and the first and second semiconductive devices 10 and 20, and the ground TSV 132 contacts the reference plane 114.

In an embodiment, the semiconductor package substrate 110 includes a core 134 with pass-through conductive pillars 136 of several uses including power (Vcc), ground (Vss) and signal transmission. The semiconductor package substrate 110 includes the die side 112, a land side 138, and a series of electrical bumps such as a land-side ball-grid array, one electrical bump of which is indicated by reference number 140.

In an embodiment, the first and second semiconductive devices 10 and 20 include at least active devices and metallization 11, and in an embodiment active devices and metallization 21,that operate at, e.g. 1 V, and the third semiconductive device 30 includes active devices and metallization 31 that operate at, e.g. 1.5 V.

In an embodiment, at least one of the first, second and third semiconductive devices 10, 20 and 30, respectively, is part of a multiple-core logic processor such as that manufactured by Intel Corporation of Santa Clara, Calif.

In an embodiment, the electrical bumps 140 provide sufficient Z-direction standoff from a printed wiring board 142 such as a motherboard 142, that at least one capacitor 144 is seated on the land side 138. In an embodiment, the board 142 has an external shell 146 such as the exterior of a computing platform.

In an embodiment, the “silicon footprint” of a computing system such as the semiconductor device package 100 is miniaturized by the TSV pitch achieved by several examples that use the embedded reference plane 114 embodiments. Useful I/O channel performance including a TSV ground (Vss) webbing network is achieved to facilitate channel-bandwidth scaling. In an embodiment, useful power-delivery loop inductance is achieved that reduces jitter and facilitates data integrity. In an embodiment, the S:G ratio is 8:1. In an embodiment, the S:G ratio is 6:1. In an embodiment, the S:G ratio is 4:1. In an embodiment, the S:G ratio is 2:1. In an embodiment, the S:G ratio is 1:1.

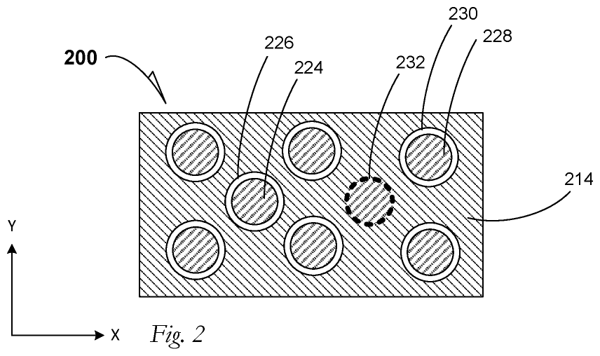

FIG. 2 is a top plan cross section 200 of an embedded reference plane 214 such as a portion of the reference plane 114 depicted in FIG. 1. A power-delivery TSV (Vcc TSV) includes a conductive via 224 that is electrically isolated from the reference plane 214 by power-via insulation 226. A signal TSV includes a conductive via 228 that is electrically isolated from the reference plane 214 by signal-via insulation 230. A ground TSV 232 contacts the reference plane 214.

In an embodiment, the power-delivery TSV 224 is insulated by a power-via insulation 226 that has a thickness in a range from 5 μm to 30 μm. In an embodiment, the signal TSV 228 is insulated by a signal-via insulation 230 that has a thickness in a range from 5 μm to 30 μm.

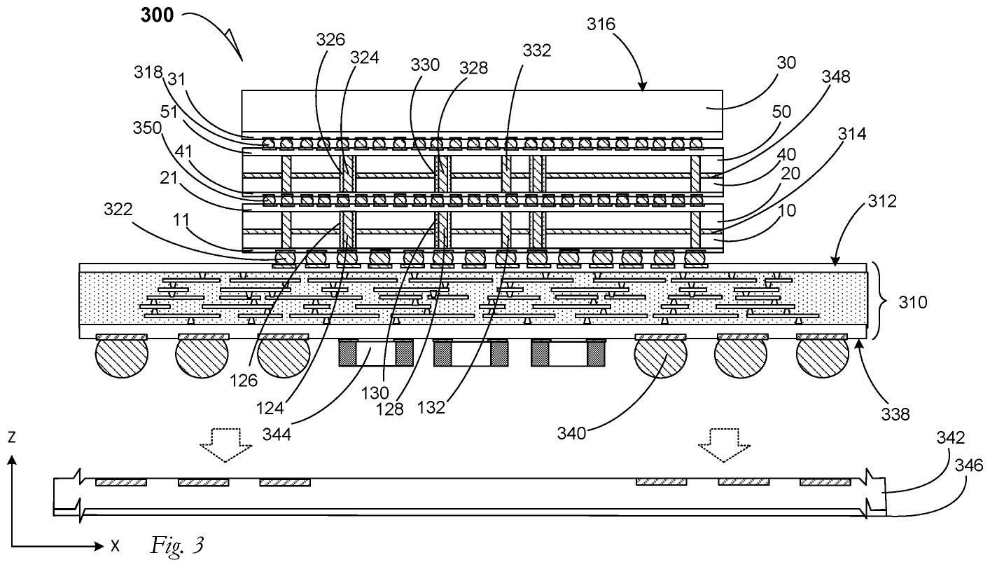

FIG. 3 is a cross-section elevation of a stacked-device through-silicon via (TSV) semiconductor package 300 according to an embodiment. First and second semiconductive devices 10 and 20, contacted by a reference plane 314, use selected reference numbers similarly to the first and second semiconductive devices 10 and 20 and the reference plane 114 depicted in FIG. 1A. A first semiconductive device 10 includes active devices and metallization 11 and it is seated on a semiconductor package substrate 310 on a die side 312.

In an embodiment, the semiconductor package substrate 310 is coreless, in contrast to the semiconductor package substrate 110 depicted in FIG. 1. Electrical connection between the first semiconductive device 10 and the semiconductor package substrate 310 is accomplished by an electrical bump array such as a ball-grid array, one electrical bump of which is indicated by reference number 322, and where the electrical bump 322 contacts both the first semiconductive device 10 and the semiconductor package substrate 310 on the die side 312.

In an embodiment, the first semiconductive device 10 contacts an embedded reference plane 314 that is between the first semiconductive device 10 and a second semiconductive device 20 that has been assembled to the first semiconductive device 10 at the reference plane 314. In an embodiment, the second semiconductive device 20 has no active devices and metallization 21, but only uses metallization 21 to couple to a fourth semiconductive device 40 and to a fifth semiconductive device 50 that are contacted by an embedded reference plane 348. In an embodiment, the fourth semiconductive device 40 has active devices and metallization 41 and the respective fourth and fifth semiconductive devices 40 and 50 use the reference plane 348 for electromagnetic shielding and/or current return path.

In an embodiment, the reference plane 314 accommodates a power-supply TSV 124, a signal TSV 128, and a reference TSV 132. The reference TSV 132 contacts the reference plane 314 and each of the power-supply TSV 124 and the signal TSV 128 are electrically isolated from the reference plane 314 by respective power-via and signal-via insulation 126 and 130. In an embodiment, the fourth semiconductive device 40 includes active devices and metallization 41 and the fourth semiconductive device 40 is flip-chip seated on the second semiconductive device 20 by an electrical bump array such as a ball-grid array, one electrical bump of which is indicated by reference number 350.

In an embodiment, a fifth semiconductive device 50 has active devices and metallization 51 and the respective fourth and fifth semiconductive devices 40 and 50 use the reference plane 348 for electromagnetic shielding and/or current return path. In an embodiment, the fifth semiconductive device 50 is referred to as a fifth semiconductive substrate 50 where only metallization 51 (e.g., silicon bridge or silicon interposer) is present.

In an embodiment, the third semiconductive device 30 includes active devices and metallization 31 and it has a backside surface 316. In an embodiment, the third semiconductive device 30 is flip-chip coupled to the fifth semiconductive device 50 by an electrical bump array such as a ball-grid array, one electrical bump of which is indicated by reference number 318. In an embodiment, a subsequent third semiconductive device 30′ (intersected in a different X-Z plane than that illustrated) is disposed on the fifth semiconductive device 50 and coupled to the third semiconductive device 30 through metallization 51 of the fifth semiconductive device 50.

In an embodiment, several through-silicon vias (TSVs) couple the first and second semiconductive devices 10 and 20 through metallizations 11 and 21 to the fourth and semiconductive devices 40 and 50. In an embodiment, a power-supply TSV 324 couples the semiconductor package substrate 310 to the fourth semiconductive device 40, a signal TSV 328 couples the semiconductor package substrate 310 to the fourth semiconductive device 40, and a ground TSV 332 contacts the reference plane 348. The power-supply TSV 324 passes through the fourth and fifth semiconductive devices 40 and 50, and the power-supply TSV 324 includes a conductive via 324 and power-via insulation 326. In an embodiment, a signal TSV 328 passes through the fourth and fifth semiconductive devices 40 and 50, and the signal TSV 328 includes a signal via 328 and signal-via insulation 330. In an embodiment, a ground TSV 332 passes through and the fourth and fifth semiconductive devices 40 and 50, and the ground TSV 332 contacts the reference plane 348.

In an embodiment, the semiconductor package substrate 310 includes a land side 338 and a series of electrical bumps such as a land-side ball-grid array, one electrical bump of which is indicated by reference number 340.

In an embodiment, the electrical bumps 340 provide sufficient Z-direction standoff from a printed wiring board 342 such as a motherboard 342, that at least one passive device such as a capacitor 344 is seated on the land side 338. In an embodiment, the board 342 has an external shell 346 such as the exterior of a computing platform.

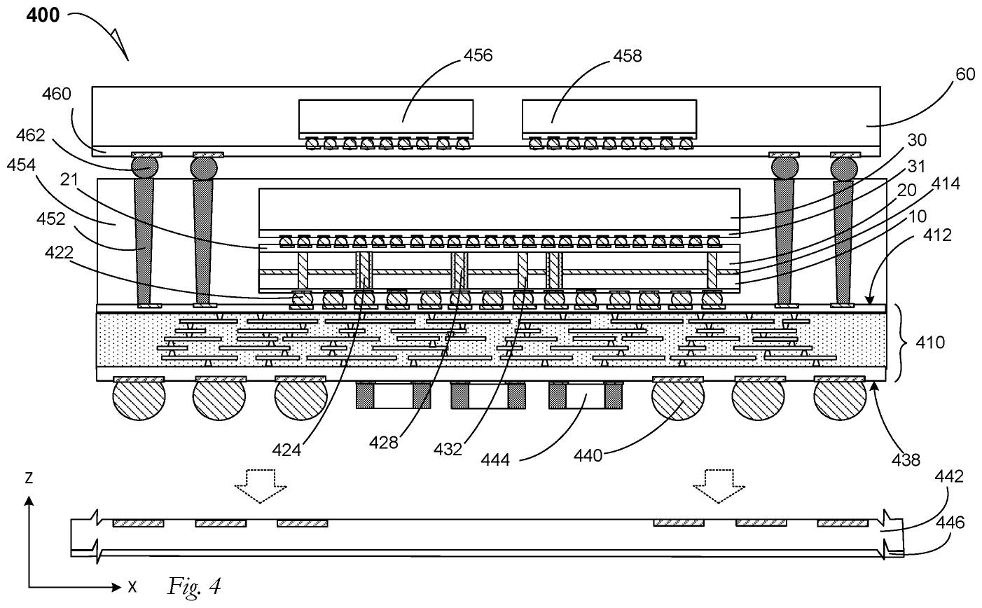

It may now be understood that a coreless semiconductor package substrate 310, depicted in FIG. 3, is combined with a first die 10 and a second die 20 depicted in FIG. 1, according to an embodiment. Added stiffness for a coreless semiconductor package is achieved by an encapsulation such as the encapsulation 454 depicted in FIG. 4.

In an embodiment, the first and second semiconductive devices 10 and 20 include at least active devices and metallization 11 and 21 that operate at, e.g. 1 V, and the third, fourth and fifth semiconductive devices 30, 40 and 50 includes active devices and metallization 31, 41 and 51 that operate at, e.g. 1.5 V, or vice versa.

FIG. 4 is a cross-section elevation of a stacked-device through-silicon via (TSV) package-on-package (POP) module semiconductor package 400 according to an embodiment. Similar to depictions in FIG. 1, a first semiconductive device 10 is seated on a semiconductor package substrate 410 on a die side 412, but the semiconductor package substrate 410 is coreless in an embodiment. In an embodiment, the semiconductor package substrate 410 includes a core such as the core 134 depicted in FIG. 1. In an embodiment, the first semiconductive device 10 contacts a reference plane 414 that is between the first semiconductive device 10 and a second semiconductive device 20 that has been assembled to the first semiconductive device 10 at the reference plane 414. In an embodiment, the second semiconductive device 20 is coupled to a third semiconductive device 30. In an embodiment, the respective first and second semiconductive devices 10 and 20 use the reference plane 414 for electromagnetic shielding and/or current return path.

In an embodiment, the third semiconductive device 30 is flip-chip coupled to the second semiconductive device 20, and it is coupled through active devices and metallization 31 to the second semiconductive device 20. In an embodiment, a subsequent third semiconductive device 30′ (intersected in a different X-Z plane than that illustrated) is disposed on the second semiconductive device 20 and coupled to the third semiconductive device 30 through metallization 21 of the semiconductive device 20. Electrical connection between the first semiconductive device 10 and the semiconductor package substrate 410 is accomplished by an electrical bump array such as a ball-grid array 422.

In an embodiment, several through-silicon vias (TSVs) couple the first and second semiconductive devices 10 to the third semiconductive device 30. In an embodiment, a power-supply TSV 424 passes through the first and second semiconductive devices 10 and 20. In an embodiment, a signal TSV 428 passes through the first and second semiconductive devices 10 and 20. In an embodiment, a ground TSV 432 passes through and the first and second semiconductive devices 10 and 20, and the ground TSV 432 contacts the reference plane 414.

In an embodiment, the semiconductor package substrate 410 includes a land side 438 and a series of electrical bumps such as a land-side ball-grid array, one electrical bump of which is indicated by reference number 440.

In an embodiment, the electrical bumps 440 provide sufficient Z-direction standoff from a printed wiring board 442 such as a motherboard 442, that at least one passive device such as a capacitor 444 is seated on the land side 438. In an embodiment, the board 442 has an external shell 446 such as the exterior of a computing platform.

In an embodiment, a package-on-package (POP) module 60 is mounted above the third semiconductive device 30, and the POP module 60 is coupled to the semiconductor package substrate 410 by POP vias 452 that penetrate an encapsulation 454 over the first, second and third semiconductive devices 10, 20 and 30, respectively.

In an embodiment, electrical communication from the signal via 428 to POP-module semiconductive devices 456 and 458 within the POP module 60, is accomplished through the POP vias 452 to a POP-module redistribution layer (POP RDL) 460, accommodated by an electrical bump 462 that is seated on the encapsulation 454 and that contacts the POP vias 452. In an embodiment, the semiconductive devices 456 and 458 are two of at least two memory dice. In an embodiment, the semiconductive devices 456 and 458 are two of at least four semiconductive devices (two intersected in a different X-Z plane than that illustrated), at least two of which are memory devices in the POP module 60, the third semiconductor device 30 is a DRAM memory device, the second semiconductive device 20 includes active devices and metallization 21 that service as a multiple-core logic processor and the first semiconductive device 10 includes active devices and metallization 11 that serve as a platform controller hub (PCH) 10.

It may now be understood that a core-containing semiconductor package substrate such as the core 134 and semiconductor package substrate 110, depicted in FIG. 1, is combined with a first die 10 and a second die 20 depicted in FIG. 4, and a package-on-package module 60 as depicted in FIG. 4.

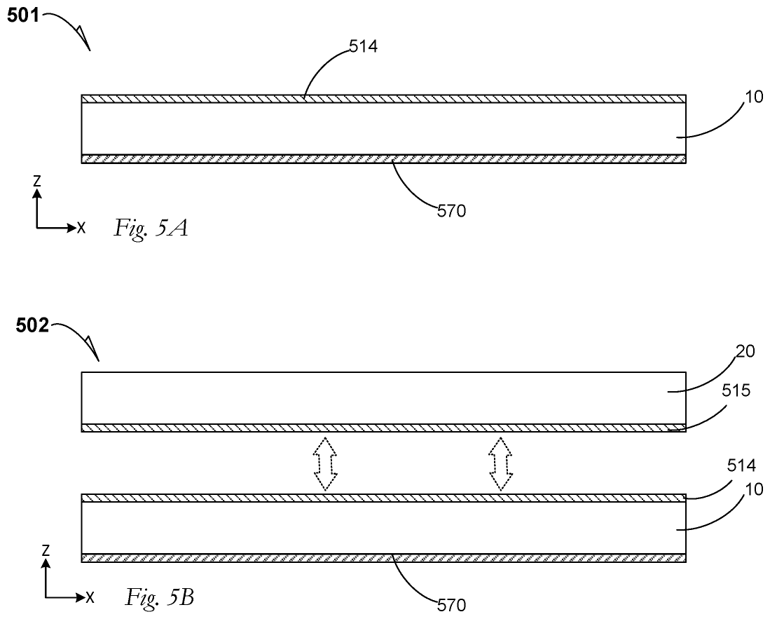

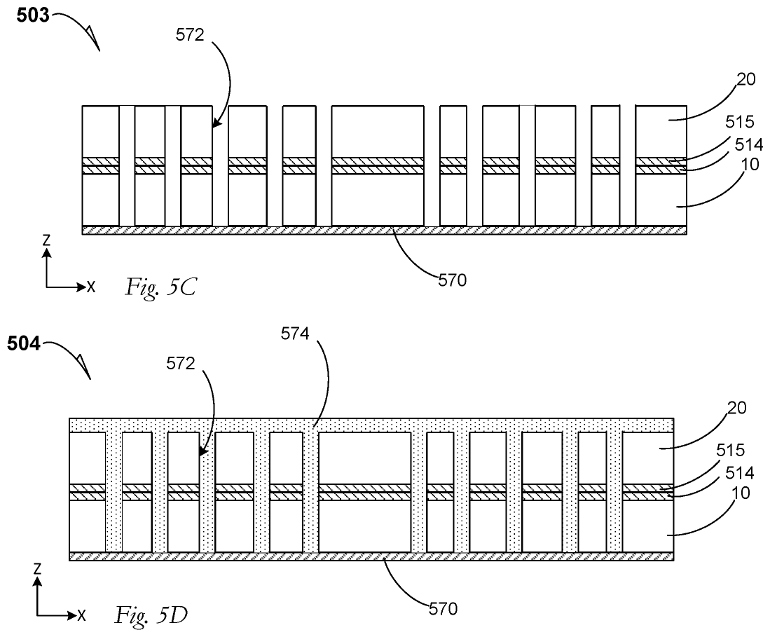

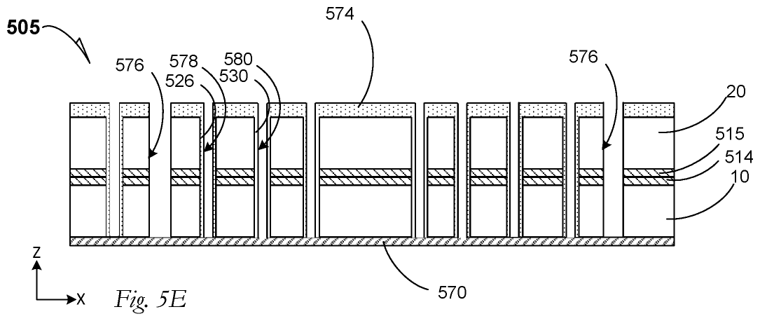

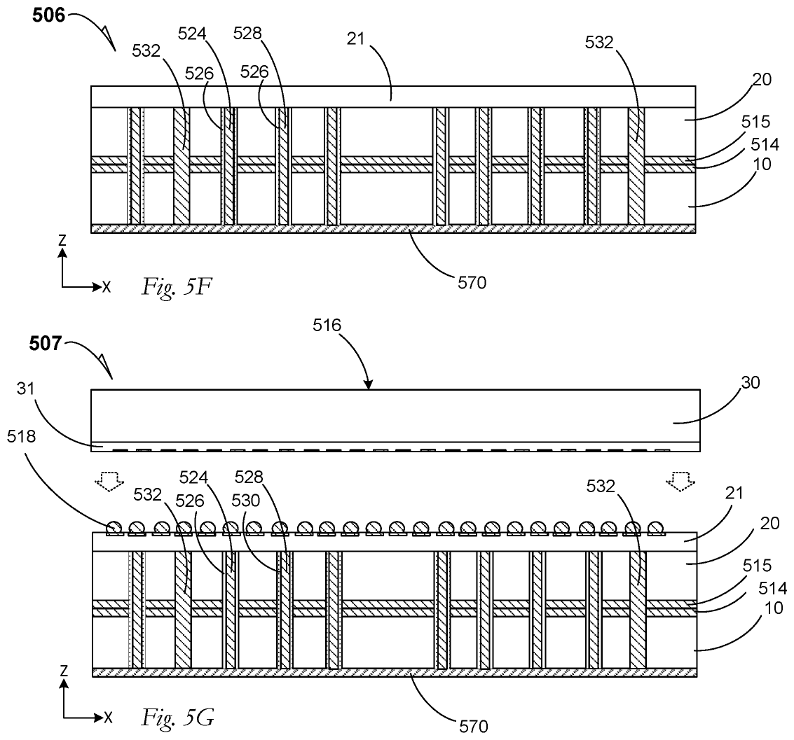

FIG. 5A is a cross-section elevation 501 of a through-silicon via with embedded reference-plane semiconductive device during assembly according to an embodiment. A first semiconductive device 10 has been contacted with a reference plane 514 as it is seated on a carrier 570.

FIG. 5B is a cross-section elevation 502 of the through-silicon via with reference-plane semiconductive device during assembly depicted in FIG. 5A after further assembly according to an embodiment. A second semiconductive device 20 has been contacted with a reference plane 515, and it is being seated on the reference plane 514 according to an embodiment. Active devices and metallization are not illustrated, and they are present during this assembly, or they are later formed such as in wafer-level semiconductor processing techniques.

FIG. 5C is a cross-section elevation 503 of the through-silicon via with an embedded reference-plane semiconductive device depicted in FIG. 5B after further processing according to an embodiment. In an embodiment, a series of contact corridors 572 (one enumerated) for TSVs are formed through the semiconductive devices 10 and 20 as well as through the reference planes 514 and 515. In an embodiment, mechanical drilling is done to form the contact corridors 572.

FIG. 5D is a cross-section elevation 504 of the through-silicon via with an embedded reference-plane semiconductive device depicted in FIG. 5C after further processing according to an embodiment. A dielectric material 574 contacts the respective first and second semiconductive devices 10 and 20, including penetrating into the series of contact corridors 572 and as far as the carrier 570. Each contact corridor 572 has an X-Y diameter that can accommodate a drill bit that is narrower than the X-Y diameter of the contact corridors 572.

FIG. 5E is a cross-section elevation 505 of the through-silicon via with an embedded reference-plane semiconductive device depicted in FIG. 5D after further processing according to an embodiment.

In an embodiment, TSVs are differentiated by the drilling process and each given location along the X-Y plane of the respective first and second semiconductive devices. Drilling leaves contact corridors useful to reference, power and signal TSVs. In an embodiment, a reference contact corridor 576 is drilled to effectively remove dielectric material 574, which allows a reference-TSV fill to contact the reference planes 514 and 515. In an embodiment a power-supply contact corridor 578 is drilled to leave power-via insulation 526. In an embodiment, a signal contact corridor 580 is drilled to leave signal-via insulation 530.

FIG. 5F is a cross-section elevation 506 of the through-silicon via with an embedded reference-plane semiconductive device depicted in FIG. 5E after further processing according to an embodiment.

In an embodiment, semiconductive devices and metallization 21 are fabricated to couple with the several TSVs. Where the several TSVs are located, a keep-out region (KOR) is fabricated using photolithography techniques. The semiconductive devices and metallization 21 are fabricated to include power TSVs 524, signal TSVs 528 and reference TSVs 532. Similarly, active devices and metallization 11 (not illustrated) are fabricated on the first semiconductive device, either before applying the carrier 570, or after removing the carrier 570.

FIG. 5G is a cross-section elevation 507 of the through-silicon via with an embedded reference-plane semiconductive device depicted in FIG. 5F during further assembly according to an embodiment. In an embodiment, a third semiconductive device 30 includes active devices and metallization 31 and it has a backside surface 516. In an embodiment, the third semiconductive device 30 is flip-chip coupled to the second semiconductive device 20 at the semiconductive devices and metallization 21, by an electrical bump array such as a ball-grid array, one electrical bump of which is indicated by reference number 518. In an embodiment, a subsequent third semiconductive device 30′ (intersected in a different X-Z plane than that illustrated) is disposed on the second semiconductive device 20 and coupled to the third semiconductive device 30 through metallization 21 of the second semiconductive device 20.

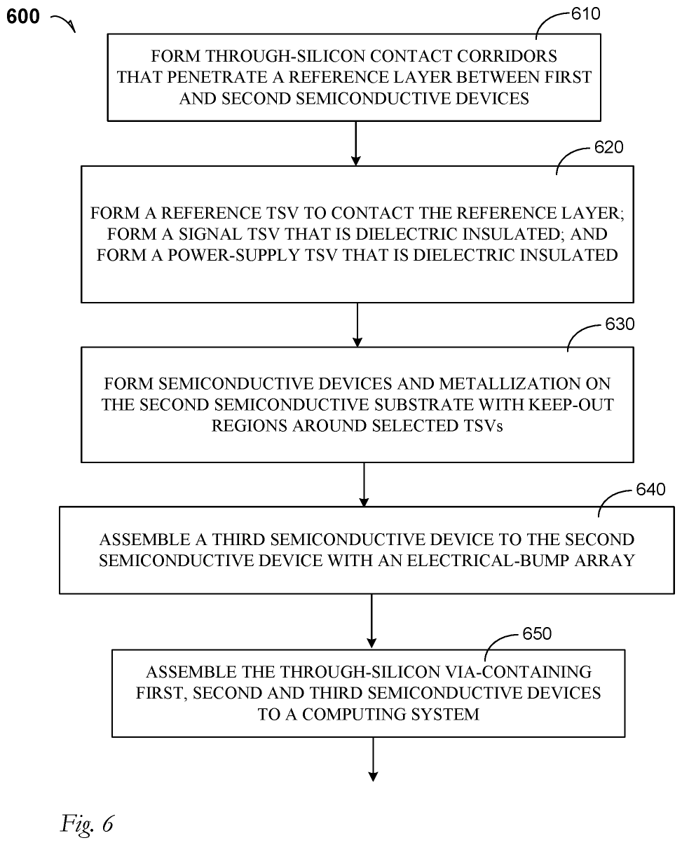

FIG. 6 is a process flow diagram 600 according to several embodiments.

At 610, the process includes forming TSVs in first and second semiconductive devices where the TSVs penetrate a reference layer.

At 620, the process includes forming a reference TSV to contact the reference layer; forming a signal TSV that is dielectric insulated; and forming a power-supply TSV that is dielectric insulated.

At 630, the process includes forming semiconductive devices and metallization on the second semiconductive device, with keep-out regions around the several TSVs.

At 640, the process includes assembling a third semiconductive device to the second semiconductive device with an electrical-bump array.

At 650, the process includes assembling the TSV-containing first, second and third semiconductive devices to a computing system.

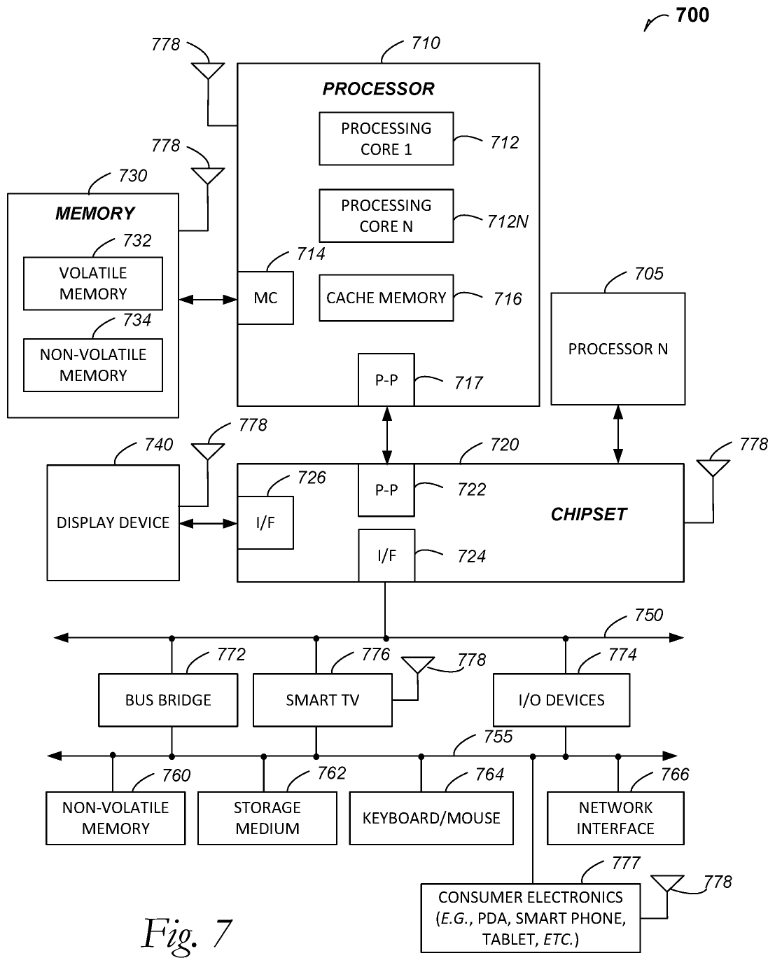

FIG. 7 is included to show an example of a higher-level device application for the disclosed embodiments. The back-to-back, embedded reference-plane sharing semiconductive device embodiments may be found in several parts of a computing system. In an embodiment, the back-to-back, reference-plane sharing semiconductive device embodiments can be part of a communications apparatus such as is affixed to a cellular communications tower. In an embodiment, a computing system 700 includes, but is not limited to, a desktop computer. In an embodiment, a computing system 700 includes, but is not limited to a laptop computer. In an embodiment, a computing system 700 includes, but is not limited to a tablet. In an embodiment, a computing system 700 includes, but is not limited to a notebook computer. In an embodiment, a computing system 700 includes, but is not limited to a personal digital assistant (PDA). In an embodiment, a computing system 700 includes, but is not limited to a server. In an embodiment, a computing system 700 includes, but is not limited to a workstation. In an embodiment, a computing system 700 includes, but is not limited to a cellular telephone. In an embodiment, a computing system 700 includes, but is not limited to a mobile computing device. In an embodiment, a computing system 700 includes, but is not limited to a smart phone. In an embodiment, a system 700 includes, but is not limited to an interne appliance. Other types of computing devices may be configured with the microelectronic device that includes back-to-back, reference-plane sharing semiconductive device embodiments.

In an embodiment, the processor 710 has one or more processing cores 712 and 712N, where 712N represents the Nth processor core inside processor 710 where N is a positive integer. In an embodiment, the electronic device system 700 using a back-to-back, embedded reference-plane sharing semiconductive device embodiment that includes multiple processors including 710 and 705, where the processor 705 has logic similar or identical to the logic of the processor 710. In an embodiment, the processing core 712 includes, but is not limited to, pre-fetch logic to fetch instructions, decode logic to decode the instructions, execution logic to execute instructions and the like. In an embodiment, the processor 710 has a cache memory 716 to cache at least one of instructions and data for the back-to-back, embedded reference-plane sharing semiconductive device embodiment in the system 700. The cache memory 716 may be organized into a hierarchal structure including one or more levels of cache memory.

In an embodiment, the processor 710 includes a memory controller 714, which is operable to perform functions that enable the processor 710 to access and communicate with memory 730 that includes at least one of a volatile memory 732 and a non-volatile memory 734. In an embodiment, the processor 710 is coupled with memory 730 and chipset 720. In an embodiment, the chipset 720 is part of a back-to-back, embedded reference-plane sharing semiconductive device embodiment depicted in any of FIGS. 1, 2, 3, 4, 5A through 5G, 6 or 7. The processor 710 may also be coupled to a wireless antenna 778 to communicate with any device configured to at least one of transmit and receive wireless signals. In an embodiment, the wireless antenna interface 778 operates in accordance with, but is not limited to, the IEEE 802.11 standard and its related family, Home Plug AV (HPAV), Ultra Wide Band (UWB), Bluetooth, WiMax, or any form of wireless communication protocol.

In an embodiment, the volatile memory 732 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. The non-volatile memory 734 includes, but is not limited to, flash memory, phase change memory (PCM), read-only memory (ROM), electrically erasable programmable read-only memory (EEPROM), or any other type of non-volatile memory device.

The memory 730 stores information and instructions to be executed by the processor 710. In an embodiment, the memory 730 may also store temporary variables or other intermediate information while the processor 710 is executing instructions. In the illustrated embodiment, the chipset 720 connects with processor 710 via Point-to-Point (PtP or P-P) interfaces 717 and 722. Either of these PtP embodiments may be achieved using a back-to-back, embedded reference-plane sharing semiconductive device embodiment as set forth in this disclosure. The chipset 720 enables the processor 710 to connect to other elements in a back-to-back, embedded reference-plane sharing semiconductive device embodiment in a system 700. In an embodiment, interfaces 717 and 722 operate in accordance with a PtP communication protocol such as the Intel® QuickPath Interconnect (QPI) or the like. In other embodiments, a different interconnect may be used.

In an embodiment, the chipset 720 is operable to communicate with the processor 710, 705N, the display device 740, and other devices 772, 776, 774, 760, 762, 764, 766, 777, etc. The chipset 720 may also be coupled to a wireless antenna 778 to communicate with any device configured to at least do one of transmit and receive wireless signals.

The chipset 720 connects to the display device 740 via the interface 726. The display 740 may be, for example, a liquid crystal display (LCD), a plasma display, cathode ray tube (CRT) display, or any other form of visual display device. In an embodiment, the processor 710 and the chipset 720 are merged into a back-to-back, embedded reference-plane sharing semiconductive device embodiment in a system. Additionally, the chipset 720 connects to one or more buses 750 and 755 that interconnect various elements 774, 760, 762, 764, and 766. Buses 750 and 755 may be interconnected together via a bus bridge 772 such as at least one back-to-back, reference-plane sharing semiconductive device embodiment. In an embodiment, the chipset 720, via interface 724, couples with a non-volatile memory 760, a mass storage device(s) 762, a keyboard/mouse 764, a network interface 766, smart TV 776, and the consumer electronics 777, etc.

In an embodiment, the mass storage device 762 includes, but is not limited to, a solid-state drive, a hard disk drive, a universal serial bus flash memory drive, or any other form of computer data storage medium. In one embodiment, the network interface 766 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the back-to-back, reference-plane sharing semiconductive device embodiments in a computing system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) can be incorporated into the processor core 712.

To illustrate the back-to-back, reference-plane sharing semiconductive device embodiments and methods disclosed herein, a non-limiting list of examples is provided herein:

Example 1 is a semiconductor package, comprising: first and second semiconductive devices mated back-to-back to a reference plane; a reference-voltage through-silicon via that penetrates the first and second semiconductive devices, and that contacts the reference plane; a power-delivery through-silicon via that penetrates the first and second semiconductive devices, that is insulated from the reference plane, and that is coupled to active devices and metallization with at least the first semiconductive device; and a signal through-silicon via that penetrates the first and second semiconductive devices, that is insulated from the reference plane, and that is coupled to active devices and metallization with at least the first semiconductive device.

In Example 2, the subject matter of Example 1 optionally includes active devices and metallization on the second semiconductive device.

In Example 3, the subject matter of any one or more of Examples 1-2 optionally include a third semiconductive device mated to the second semiconductive device; wherein the reference-voltage through-silicon via is coupled to the third semiconductive device, wherein the power-delivery through-silicon via is coupled to the third semiconductive device, and wherein the signal through-silicon via is coupled to the third semiconductive device.

In Example 4, the subject matter of any one or more of Examples 1-3 optionally include wherein the first semiconductive device is on a semiconductor package substrate.

In Example 5, the subject matter of any one or more of Examples 1-4 optionally include a semiconductor package substrate including a core, a die side and a land side; wherein the first semiconductive device is coupled to a semiconductor package substrate die side by contact through an electrical-bump array; a land-side ball-grid array mated to the semiconductor package substrate land side; and at least one passive device mated to the semiconductor package substrate land side.

In Example 6, the subject matter of any one or more of Examples 1-5 optionally include a semiconductor package substrate mated to the first semiconductive device by an electrical-bump array; wherein the semiconductor package substrate includes a core including a die side and a land side; a land-side ball-grid array mated to the semiconductor package substrate land side; and a printed wiring board coupled to the land-side ball-grid array.

In Example 7, the subject matter of Example 1 optionally includes a semiconductor package substrate including a core, a die side and a land side; wherein the first semiconductive device is coupled to a semiconductor package substrate die side by contact through an electrical-bump array; a land-side ball-grid array mated to the semiconductor package substrate land side; at least one passive device mated to the semiconductor package substrate land side; and a printed wiring board coupled to the land-side ball-grid array.

In Example 8, the subject matter of any one or more of Examples 1-7 optionally include a semiconductor package substrate including a core, a die side and a land side; wherein the first semiconductive device is coupled to a semiconductor package substrate die side by contact through an electrical-bump array; a land-side ball-grid array mated to the semiconductor package substrate land side; at least one passive device mated to the semiconductor package substrate land side; a printed wiring board coupled to the land-side ball-grid array; and wherein the printed wiring board includes an external shell.

In Example 9, the subject matter of any one or more of Examples 1-8 optionally include fourth and fifth semiconductive devices mated back-to-back to a reference plane, wherein the fourth semiconductive device contacts the second semiconductive device through an electrical-bump array; a reference-voltage through-silicon via that penetrates the fourth and fifth semiconductive devices, and that contacts the reference plane; a power-delivery through-silicon via that penetrates the fourth and fifth semiconductive devices, that is insulated from the reference plane, and that is coupled to active devices and metallization with at least the fourth semiconductive device; and a signal through-silicon via that penetrates the fourth and fifth semiconductive devices, that is insulated from the reference plane, and that is coupled to active devices and metallization with at least the fourth semiconductive device.

In Example 10, the subject matter of any one or more of Examples 1-9 optionally include fourth and fifth semiconductive devices mated back-to-back to a reference plane, wherein the fourth semiconductive device contacts the second semiconductive device through an electrical-bump array; a reference-voltage through-silicon via that penetrates the fourth and fifth semiconductive devices, and that contacts the reference plane; a power-delivery through-silicon via that penetrates the fourth and fifth semiconductive devices, that is insulated from the reference plane, and that is coupled to active devices and metallization with at least the fourth semiconductive device; a signal through-silicon via that penetrates the fourth and fifth semiconductive devices, that is insulated from the reference plane, and that is coupled to active devices and metallization with at least the fourth semiconductive device; and active devices and metallization on the fifth semiconductive device.

In Example 11, the subject matter of any one or more of Examples 1-10 optionally include a semiconductor package substrate mated to the first semiconductive device by an electrical-bump array; wherein the semiconductor package substrate includes a coreless architecture including a die side and a land side; a land-side ball-grid array mated to the semiconductor package substrate land side; at least one passive device mated to the semiconductor package substrate land side; fourth and fifth semiconductive devices mated back-to-back to a reference plane, wherein the fourth semiconductive device contacts the second semiconductive device through an electrical-bump array; a reference-voltage through-silicon via that penetrates the fourth and fifth semiconductive devices, and that contacts the reference plane; a power-delivery through-silicon via that penetrates the fourth and fifth semiconductive devices, that is insulated from the reference plane, and that is coupled to active devices and metallization with at least the fourth semiconductive device; and a signal through-silicon via that penetrates the fourth and fifth semiconductive devices, that is insulated from the reference plane, and that is coupled to active devices and metallization with at least the fourth semiconductive device.

In Example 12, the subject matter of any one or more of Examples 1-11 optionally include a semiconductor package substrate mated to the first semiconductive device by an electrical-bump array; wherein the semiconductor package substrate includes a coreless architecture including a die side and a land side; a land-side ball-grid array mated to the semiconductor package substrate land side; at least one passive device mated to the semiconductor package substrate land side; fourth and fifth semiconductive devices mated back-to-back to a reference plane, wherein the fourth semiconductive device contacts the second semiconductive device through an electrical-bump array; a reference-voltage through-silicon via that penetrates the fourth and fifth semiconductive devices, and that contacts the reference plane; a power-delivery through-silicon via that penetrates the fourth and fifth semiconductive devices, that is insulated from the reference plane, and that is coupled to active devices and metallization with at least the fourth semiconductive device; a signal through-silicon via that penetrates the fourth and fifth semiconductive devices, that is insulated from the reference plane, and that is coupled to active devices and metallization with at least the fourth semiconductive device; a printed wiring board coupled to the land-side ball-grid array; and wherein the printed wiring board includes an external shell.

In Example 13, the subject matter of any one or more of Examples 1-12 optionally include a semiconductor package substrate mated to the first semiconductive device; a package-on-package module coupled to the semiconductor package substrate; and a third semiconductive device mated to the second semiconductive device and below the package-on-package module, wherein the reference-voltage through-silicon via is coupled to the third semiconductive device, wherein the power-delivery through-silicon via is coupled to the third semiconductive device, and wherein the signal through-silicon via is coupled to the third semiconductive device.

In Example 14, the subject matter of any one or more of Examples 1-13 optionally include a semiconductor package substrate mated to the first semiconductive device; a package-on-package module coupled to the semiconductor package substrate, wherein the package-on-package module includes at least two memory devices; and a third semiconductive device mated to the second semiconductive device and below the package-on-package module, wherein the reference-voltage through-silicon via is coupled to the third semiconductive device, wherein the power-delivery through-silicon via is coupled to the third semiconductive device, and wherein the signal through-silicon via is coupled to the third semiconductive device.

In Example 15, the subject matter of any one or more of Examples 1-14 optionally include a semiconductor package substrate mated to the first semiconductive device; a package-on-package module coupled to the semiconductor package substrate, wherein the package-on-package module is coupled through a molding mass, and wherein the package-on package module includes at least one semiconductive device; a third semiconductive device mated to the second semiconductive device and below the package-on-package module, wherein the reference-voltage through-silicon via is coupled to the third semiconductive device, wherein the power-delivery through-silicon via is coupled to the third semiconductive device, and wherein the signal through-silicon via is coupled to the third semiconductive device; at least one passive device mated to the semiconductor package substrate land side; fourth and fifth semiconductive devices mated back-to-back to a reference plane, wherein the fourth semiconductive device contacts the second semiconductive device through an electrical-bump array; a reference-voltage through-silicon via that penetrates the fourth and fifth semiconductive device, and that contacts the reference plane; a power-delivery through-silicon via that penetrates the fourth and fifth semiconductive devices, that is insulated from the reference plane, and that is coupled to active devices and metallization with at least the fourth semiconductive device; and a signal through-silicon via that penetrates the fourth and fifth semiconductive devices, that is insulated from the reference plane, and that is coupled to active devices and metallization with at least the fourth semiconductive device.

Example 16 is a method of assembling a semiconductor package, comprising: forming through-silicon contact corridors that penetrate a reference layer between first and second semiconductive devices; forming a reference through-silicon via in a contact corridor that contacts the reference layer; forming a power-delivery through-silicon via in a contact corridor that is dielectric insulated from the reference layer; and forming a signal through-silicon via in a contact corridor that is dielectric insulated from the reference layer.

In Example 17, the subject matter of Example 16 optionally includes assembling a third semiconductive device to the second semiconductive device by an electrical bump array that contacts the third semiconductive device and the second semiconductive device.

In Example 18, the subject matter of any one or more of Examples 16-17 optionally include assembling the first semiconductive device to a semiconductor package substrate; and assembling a third semiconductive device to the second semiconductive device by an electrical bump array that contacts the third semiconductive device and the second semiconductive device.

In Example 19, the subject matter of any one or more of Examples 16-18 optionally include forming through-silicon contact corridors that penetrate a reference layer between fourth and fifth semiconductive devices; forming a reference through-silicon via in a contact corridor that contacts the reference layer; forming a power-delivery through-silicon via in a contact corridor that is dielectric insulated from the reference layer; forming a signal through-silicon via in a contact corridor that is dielectric insulated from the reference layer; and assembling the fourth semiconductive device to the second semiconductive device through an electrical bump array.

Example 20 is a computing system, comprising: a semiconductor package substrate including a die side and a land side; first and second semiconductive devices mated back-to-back to a reference plane, wherein the first semiconductive device is mounted on the semiconductor package substrate die side through an electrical contact array; a reference-voltage through-silicon via that penetrates the first and second semiconductive devices, and that contacts the reference plane; a power-delivery through-silicon via that penetrates the first and second semiconductive devices, that is insulated from the reference plane, and that is coupled to active devices and metallization with at least the first semiconductive device; a signal through-silicon via that penetrates the first and second semiconductive devices, that is insulated from the reference plane, and that is coupled to active devices and metallization with at least the first semiconductive device; a third semiconductive device mated to the second semiconductive device; wherein the reference-voltage through-silicon via is coupled to the third semiconductive device, wherein the power-delivery through-silicon via is coupled to the third semiconductive device, and wherein the signal through-silicon via is coupled to the third semiconductive device; wherein at least one of the first, second and third semiconductive devices is part of a multiple-core logic processor; a land-side ball-grid array mated to the semiconductor package substrate land side; and a printed wiring board coupled to the land-side ball-grid array; and wherein the first, second and third semiconductive devices are part of a chipset.

In Example 21, the subject matter of Example 20 optionally includes active devices and metallization on the second semiconductive device.

In Example 22, the subject matter of any one or more of Examples 20-21 optionally include fourth and fifth semiconductive devices mated back-to-back to a reference plane, wherein the fourth semiconductive device contacts the second semiconductive device through an electrical-bump array; a reference-voltage through-silicon via that penetrates the fourth and fifth semiconductive devices, and that contacts the reference plane; a power-delivery through-silicon via that penetrates the fourth and fifth semiconductive devices, that is insulated from the reference plane, and that is coupled to active devices and metallization with at least the fourth semiconductive device; and a signal through-silicon via that penetrates the fourth and fifth semiconductive devices, that is insulated from the reference plane, and that is coupled to active devices and metallization with at least the fourth semiconductive device.

In Example 23, the subject matter of any one or more of Examples 20-22 optionally include a package-on-package module coupled to the semiconductor package substrate, wherein the package-on-package module incudes at least two memory dice.The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electrical device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosed embodiments should be determined with reference to the appended claims, along with the full scope of equivalents to which such claims are entitled.

1. A semiconductor package, comprising:
first and second semiconductive devices mated back-to-back to a reference plane;
a reference-voltage through-silicon via that penetrates the first and second semiconductive devices, and that contacts the reference plane;
a power-delivery through-silicon via that penetrates the first and second semiconductive devices, that is insulated from the reference plane, and that is coupled to active devices and metallization with at least the first semiconductive device; and
a signal through-silicon via that penetrates the first and second semiconductive devices, that is insulated from the reference plane, and that is coupled to active devices and metallization with at least the first semiconductive device.

2. The semiconductor package of claim 1, further including active devices and metallization on the second semiconductive device.

3. The semiconductor package of claim 1, further including:
a third semiconductive device mated to the second semiconductive device;
wherein the reference-voltage through-silicon via is coupled to the third semiconductive device, wherein the power-delivery through-silicon via is coupled to the third semiconductive device, and wherein the signal through-silicon via is coupled to the third semiconductive device.

4. The semiconductor package of claim 1, wherein the first semiconductive device is on a semiconductor package substrate.

5. The semiconductor package of claim 1, further including:
a semiconductor package substrate including a core, a die side and a land side;
wherein the first semiconductive device is coupled to a semiconductor package substrate die side by contact through an electrical-bump array;
a land-side ball-grid array mated to the semiconductor package substrate land side; and
at least one passive device mated to the semiconductor package substrate land side.

6. The semiconductor package of claim 1, further including:
a semiconductor package substrate mated to the first semiconductive device by an electrical-bump array;
wherein the semiconductor package substrate includes a core including a die side and a land side;
a land-side ball-grid array mated to the semiconductor package substrate land side; and
a printed wiring board coupled to the land-side ball-grid array.

7. The semiconductor package of claim 1, further including:
a semiconductor package substrate including a core, a die side and a land side;
wherein the first semiconductive device is coupled to a semiconductor package substrate die side by contact through an electrical-bump array;
a land-side ball-grid array mated to the semiconductor package substrate land side;
at least one passive device mated to the semiconductor package substrate land side; and
a printed wiring board coupled to the land-side ball-grid array.

8. The semiconductor package of claim 1, further including:
a semiconductor package substrate including a core, a die side and a land side;
wherein the first semiconductive device is coupled to a semiconductor package substrate die side by contact through an electrical-bump array;
a land-side ball-grid array mated to the semiconductor package substrate land side;
at least one passive device mated to the semiconductor package substrate land side;
a printed wiring board coupled to the land-side ball-grid array; and
wherein the printed wiring board includes an external shell.

9. The semiconductor package of claim 1, further including:
fourth and fifth semiconductive devices mated back-to-back to a reference plane, wherein the fourth semiconductive device contacts the second semiconductive device through an electrical-bump array;
a reference-voltage through-silicon via that penetrates the fourth and fifth semiconductive devices, and that contacts the reference plane;
a power-delivery through-silicon via that penetrates the fourth and fifth semiconductive devices, that is insulated from the reference plane, and that is coupled to active devices and metallization with at least the fourth semiconductive device; and
a signal through-silicon via that penetrates the fourth and fifth semiconductive devices, that is insulated from the reference plane, and that is coupled to active devices and metallization with at least the fourth semiconductive device.

10. The semiconductor package of claim 1, further including:
fourth and fifth semiconductive devices mated back-to-back to a reference plane, wherein the fourth semiconductive device contacts the second semiconductive device through an electrical-bump array;
a reference-voltage through-silicon via that penetrates the fourth and fifth semiconductive devices, and that contacts the reference plane;
a power-delivery through-silicon via that penetrates the fourth and fifth semiconductive devices, that is insulated from the reference plane, and that is coupled to active devices and metallization with at least the fourth semiconductive device;
a signal through-silicon via that penetrates the fourth and fifth semiconductive devices, that is insulated from the reference plane, and that is coupled to active devices and metallization with at least the fourth semiconductive device; and
active devices and metallization on the fifth semiconductive device.

11. The semiconductor package of claim 1, further including:
a semiconductor package substrate mated to the first semiconductive device by an electrical-bump array;
wherein the semiconductor package substrate includes a coreless architecture including a die side and a land side;
a land-side ball-grid array mated to the semiconductor package substrate land side;
at least one passive device mated to the semiconductor package substrate land side;
fourth and fifth semiconductive devices mated back-to-back to a reference plane, wherein the fourth semiconductive device contacts the second semiconductive device through an electrical-bump array;
a reference-voltage through-silicon via that penetrates the fourth and fifth semiconductive devices, and that contacts the reference plane;
a power-delivery through-silicon via that penetrates the fourth and fifth semiconductive devices, that is insulated from the reference plane, and that is coupled to active devices and metallization with at least the fourth semiconductive device; and
a signal through-silicon via that penetrates the fourth and fifth semiconductive devices, that is insulated from the reference plane, and that is coupled to active devices and metallization with at least the fourth semiconductive device.

12. The semiconductor package of claim 1, further including:
a semiconductor package substrate mated to the first semiconductive device by an electrical-bump array;
wherein the semiconductor package substrate includes a coreless architecture including a die side and a land side;
a land-side ball-grid array mated to the semiconductor package substrate land side;
at least one passive device mated to the semiconductor package substrate land side;
fourth and fifth semiconductive devices mated back-to-back to a reference plane, wherein the fourth semiconductive device contacts the second semiconductive device through an electrical-bump array;
a reference-voltage through-silicon via that penetrates the fourth and fifth semiconductive devices, and that contacts the reference plane;
a power-delivery through-silicon via that penetrates the fourth and fifth semiconductive devices, that is insulated from the reference plane, and that is coupled to active devices and metallization with at least the fourth semiconductive device;
a signal through-silicon via that penetrates the fourth and fifth semiconductive devices, that is insulated from the reference plane, and that is coupled to active devices and metallization with at least the fourth semiconductive device;
a printed wiring board coupled to the land-side ball-grid array; and
wherein the printed wiring board includes an external shell.

13. The semiconductor package of claim 1, further including:
a semiconductor package substrate mated to the first semiconductive device;
a package-on-package module coupled to the semiconductor package substrate; and
a third semiconductive device mated to the second semiconductive device and below the package-on-package module, wherein the reference-voltage through-silicon via is coupled to the third semiconductive device, wherein the power-delivery through-silicon via is coupled to the third semiconductive device, and wherein the signal through-silicon via is coupled to the third semiconductive device.

14. The semiconductor package of claim 1, further including:
a semiconductor package substrate mated to the first semiconductive device;
a package-on-package module coupled to the semiconductor package substrate, wherein the package-on-package module includes at least two memory devices; and
a third semiconductive device mated to the second semiconductive device and below the package-on-package module, wherein the reference-voltage through-silicon via is coupled to the third semiconductive device, wherein the power-delivery through-silicon via is coupled to the third semiconductive device, and wherein the signal through-silicon via is coupled to the third semiconductive device.

15. The semiconductor package of claim 1, further including:
a semiconductor package substrate mated to the first semiconductive device;
a package-on-package module coupled to the semiconductor package substrate, wherein the package-on-package module is coupled through a molding mass, and wherein the package-on package module includes at least one semiconductive device;
a third semiconductive device mated to the second semiconductive device and below the package-on-package module, wherein the reference-voltage through-silicon via is coupled to the third semiconductive device, wherein the power-delivery through-silicon via is coupled to the third semiconductive device, and wherein the signal through-silicon via is coupled to the third semiconductive device;
at least one passive device mated to the semiconductor package substrate land side;
fourth and fifth semiconductive devices mated back-to-back to a reference plane, wherein the fourth semiconductive device contacts the second semiconductive device through an electrical-bump array;
a reference-voltage through-silicon via that penetrates the fourth and fifth semiconductive device, and that contacts the reference plane;
a power-delivery through-silicon via that penetrates the fourth and fifth semiconductive devices, that is insulated from the reference plane, and that is coupled to active devices and metallization with at least the fourth semiconductive device; and
a signal through-silicon via that penetrates the fourth and fifth semiconductive devices, that is insulated from the reference plane, and that is coupled to active devices and metallization with at least the fourth semiconductive device.

16. A method of assembling a semiconductor package, comprising:
forming through-silicon contact corridors that penetrate a reference layer between first and second semiconductive devices;
forming a reference through-silicon via in a contact corridor that contacts the reference layer;
forming a power-delivery through-silicon via in a contact corridor that is dielectric insulated from the reference layer; and
forming a signal through-silicon via in a contact corridor that is dielectric insulated from the reference layer.

17. The method of claim 16, further including assembling a third semiconductive device to the second semiconductive device by an electrical bump array that contacts the third semiconductive device and the second semiconductive device.

18. The method of claim 16, further including:
assembling the first semiconductive device to a semiconductor package substrate; and
assembling a third semiconductive device to the second semiconductive device by an electrical bump array that contacts the third semiconductive device and the second semiconductive device.

19. The method of claim 16, further including:
forming through-silicon contact corridors that penetrate a reference layer between fourth and fifth semiconductive devices;
forming a reference through-silicon via in a contact corridor that contacts the reference layer;
forming a power-delivery through-silicon via in a contact corridor that is dielectric insulated from the reference layer;
forming a signal through-silicon via in a contact corridor that is dielectric insulated from the reference layer; and assembling the fourth semiconductive device to the second semiconductive device through an electrical bump array.

20. A computing system, comprising:
a semiconductor package substrate including a die side and a land side;
first and second semiconductive devices mated back-to-back to a reference plane, wherein the first semiconductive device is mounted on the semiconductor package substrate die side through an electrical contact array;
a reference-voltage through-silicon via that penetrates the first and second semiconductive devices, and that contacts the reference plane;
a power-delivery through-silicon via that penetrates the first and second semiconductive devices, that is insulated from the reference plane, and that is coupled to active devices and metallization with at least the first semiconductive device;
a signal through-silicon via that penetrates the first and second semiconductive devices, that is insulated from the reference plane, and that is coupled to active devices and metallization with at least the first semiconductive device;
a third semiconductive device mated to the second semiconductive device;
wherein the reference-voltage through-silicon via is coupled to the third semiconductive device, wherein the power-delivery through-silicon via is coupled to the third semiconductive device, and wherein the signal through-silicon via is coupled to the third semiconductive device;
wherein at least one of the first, second and third semiconductive devices is part of a multiple-core logic processor;
a land-side ball-grid array mated to the semiconductor package substrate land side; and
a printed wiring board coupled to the land-side ball-grid array; and
wherein the first, second and third semiconductive devices are part of a chipset.

21. The semiconductor package of claim 20, further including active devices and metallization on the second semiconductive device.

22. The computing system of claim 20, further including:
fourth and fifth semiconductive devices mated back-to-back to a reference plane, wherein the fourth semiconductive device contacts the second semiconductive device through an electrical-bump array;
a reference-voltage through-silicon via that penetrates the fourth and fifth semiconductive devices, and that contacts the reference plane;
a power-delivery through-silicon via that penetrates the fourth and fifth semiconductive devices, that is insulated from the reference plane, and that is coupled to active devices and metallization with at least the fourth semiconductive device; and
a signal through-silicon via that penetrates the fourth and fifth semiconductive devices, that is insulated from the reference plane, and that is coupled to active devices and metallization with at least the fourth semiconductive device.

23. The computing system of claim 20, further including
a package-on-package module coupled to the semiconductor package substrate, wherein the
package-on-package module incudes at least two memory dice.
